(19) United States
(12) Patent Application Publication
(10) Pub. No.: US 2017/0038408 A1
(43) Pub. Date: Feb. 9, 2017

(54) PIEZOELECTRIC SHOCK SENSOR AND METHOD OF MANUFACTURING THE SAME

(71) Applicant: SAMSUNG ELECTRO-MECHANICS CO., LTD., Suwon-si (KR)

(72) Inventors: Mun Su HA, Suwon-si (KR); Hong Yeon CHO, Suwon-si (KR); Yong Koo KIM, Suwon-si (KR)

(21) Appl. No.: 15/041,509

(22) Filed: Feb. 11, 2016

(30) Foreign Application Priority Data
Aug. 6, 2015 (KR) 10-2015-0111242

(51) Int. Cl. G01P 15/09; H01L 41/27

(52) U.S. Cl. CPC G01P 15/0922; H01L 41/27

(57) ABSTRACT

A piezoelectric shock sensor includes a lower cover, a piezoelectric element in which first and second piezoelectric sheets are stacked, and an upper cover. Each of the first and second piezoelectric sheets has a cantilever portion and a frame portion formed integrally with each other. First and second internal electrodes are formed on the first and second piezoelectric sheets, respectively. First and second lead portions, respectively electrically connected to the first and second internal electrodes, are exposed through opposing side surfaces of the piezoelectric element.

### CROSS-REFERENCE TO RELATED APPLICATION

This application claims the benefit of priority to Korean Patent Application No. 10-2015-0111242, filed on Aug. 6, 2015 with the Korean Intellectual Property Office, the disclosure of which is incorporated herein by reference.

### BACKGROUND

The present disclosure relates to a piezoelectric shock sensor element and a method of manufacturing the same.

A piezoelectric shock sensor is used to investigate a cause of an abnormal vibration or operation of an electronic product or a machine. Piezoelectric shock sensors have recently been designed to be integrated within computers or mobile phones, and to provide low noise and high quality sensing.

The piezoelectric shock sensor according to the related art has a structure in which a fired piezoelectric body is enclosed by package materials in four directions (or, for example, in all directions).

The piezoelectric shock sensor of the related art may be manufactured by bonding two package structures having cavities formed therein to form intermediate layers providing upper and lower surfaces (or, alternatively, left and right surfaces) of a casing surrounding the fired piezoelectric body. Then, packages are bonded as covers to the left and right surfaces (or, alternatively, the upper and lower surfaces) of the casing surrounding the piezoelectric body.

Alternatively, the piezoelectric shock sensor may be manufactured by forming and polarizing two package structures on upper and lower surfaces (or, alternatively, left and right surfaces) of the piezoelectric body. In turn, one end of an electrode is cut to form a cantilever. Then, packages are bonded as covers to the piezoelectric body.

However, in the cantilever structures described above and the associated manufacturing methods, steps for performing a polarizing process and for cutting the piezoelectric body are required in order to manufacture internal electrodes in a cantilever shape.

However, the manufacturing processes become complicated when processes for cutting the piezoelectric body are introduced, and errors in the dimensions of the piezoelectric shock sensor may be introduced by such steps when the piezoelectric body is cut. Improved piezoelectric shock sensors and methods of manufacturing such piezoelectric shock sensors are therefore needed.

### SUMMARY

A piezoelectric shock sensor is capable of being manufactured by a simplified process and has a reduced dimensional error. The process for manufacturing the piezoelectric shock sensor does not include cutting of a piezoelectric body.

According to an aspect of the present disclosure, a piezoelectric shock sensor includes a lower cover, a piezoelectric element in which first and second piezoelectric sheets are stacked, and an upper cover. Each of the first and second piezoelectric sheets has a cantilever portion and a frame portion formed integrally with each other. First and second internal electrodes are formed on the first and second piezoelectric sheets, respectively. First and second lead portions, respectively electrically connected to the first and second internal electrodes, are exposed through opposing side surfaces of the piezoelectric element.

According to other aspects of the disclosure, methods are provided for manufacturing the piezoelectric shock sensor.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a perspective view schematically illustrating a piezoelectric shock sensor according to an exemplary embodiment;

FIG. 2 is a perspective view of the piezoelectric shock sensor of FIG. 1 from which external electrodes are removed;

FIG. 3 is an exploded perspective view of the piezoelectric shock sensor of FIGS. 1 and 2;

FIG. 4A is a perspective view illustrating a first piezoelectric sheet of a piezoelectric element in the piezoelectric shock sensor of FIG. 1;

FIG. 4B is a perspective view illustrating a second piezoelectric sheet of a piezoelectric element in the piezoelectric shock sensor of FIG. 1; and

FIGS. 5A through 5D are perspective views illustrating sequential steps of a method of manufacturing a piezoelectric shock sensor according to an exemplary embodiment.

### DETAILED DESCRIPTION

Exemplary embodiments of the present disclosure will now be described in detail with reference to the accompanying drawings.

Piezoelectric Shock Sensor

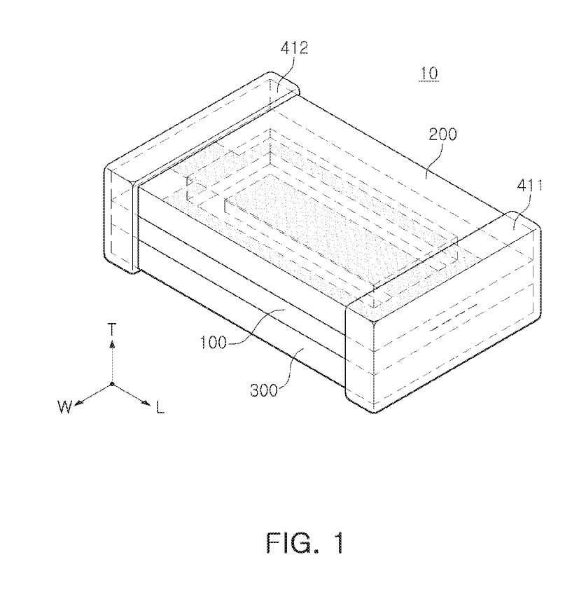

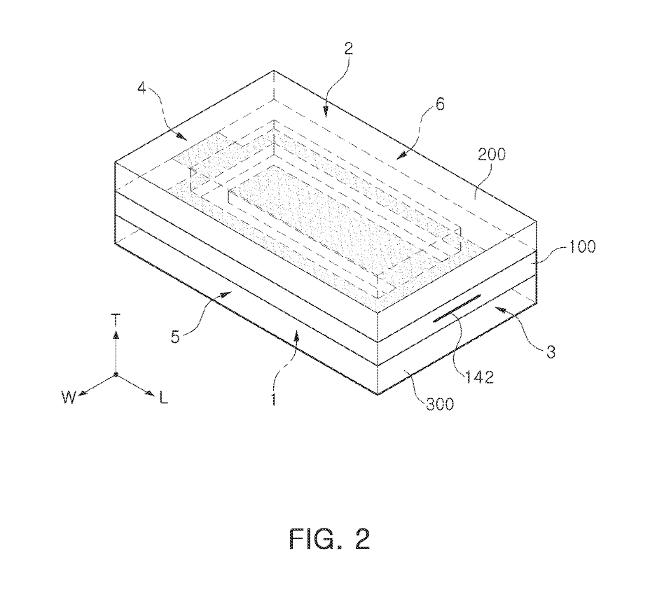

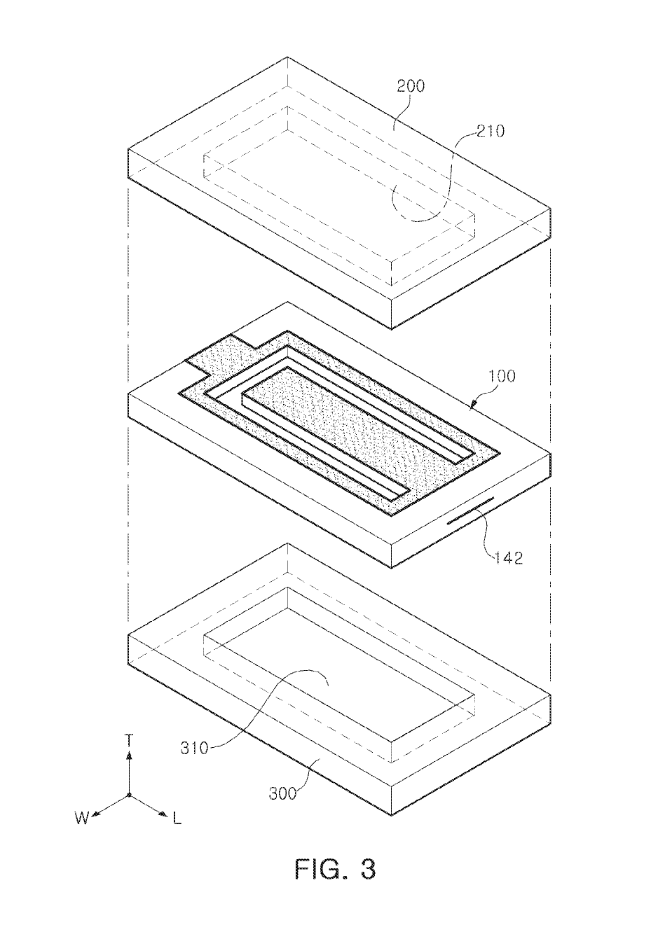

FIG. 1 is a perspective view schematically illustrating a piezoelectric shock sensor according to an exemplary embodiment; FIG. 2 is a perspective view of the piezoelectric shock sensor of FIG. 1 from which external electrodes are removed; and FIG. 3 is an exploded perspective view of the piezoelectric shock sensor of FIGS. 1 and 2.

Referring to FIGS. 1 through 3, a piezoelectric shock sensor 10 according to the present exemplary embodiment may include a piezoelectric element 100 and upper and lower covers 200 and 300.

For convenience of explanation, each surface of a multilayer body including the piezoelectric element 100 and the upper and lower covers 200 and 300 will be defined. First and second surfaces 1 and 2 refer to lower and upper surfaces of the multilayer body, respectively; third and fourth surfaces 3 and 4 of the multilayer body refer to opposing end surfaces of the multilayer body in a length direction; and fifth and sixth surfaces 5 and 6 of the multilayer body refer to opposing side surfaces of the multilayer body in a width direction.

The lower cover 300 may be formed by stacking one or more dielectric layers on which internal electrodes are not formed, and may be formed of a piezoelectric material, if necessary. The lower cover 300 may be disposed on or in contact with a lower surface of the piezoelectric element 100.

The upper cover 200 may be formed by stacking one or more dielectric layers on which internal electrodes are not formed, and may be formed of a piezoelectric material, if necessary. The upper cover 200 may be disposed on or in contact with an upper surface of the piezoelectric element 100.

Here, a first concave portion 310 having a cavity shape may be formed in an upper surface of the lower cover 300, and a second concave portion 210 having a cavity shape may be formed in a lower surface of the upper cover 200. Here, the first and second concave portions 310 and 210 may have a length and a width larger than those of first and second internal electrodes of a piezoelectric element 100 to be described below. Additionally, the first and second concave portions 310 and 210 respectively formed in the lower cover 300 and upper cover 200 generally do not extend through the lower and upper covers, but instead form cavities within the covers.

In the present exemplary embodiment, the first and second concave portions 310 and 210 each formed in the lower and upper covers 300 and 200 may serve to secure a space in which first and second internal electrodes may freely vibrate when the piezoelectric element 100 vibrates. The presence of the first and second concave portions 310 and 210 may thus prevent damage to the upper and lower covers 200 and 300 due to the vibrations of the piezoelectric element 100, and prevent hindrance of the transfer of the vibrations of the first and second internal electrodes when the piezoelectric shock sensor 10 is driven.

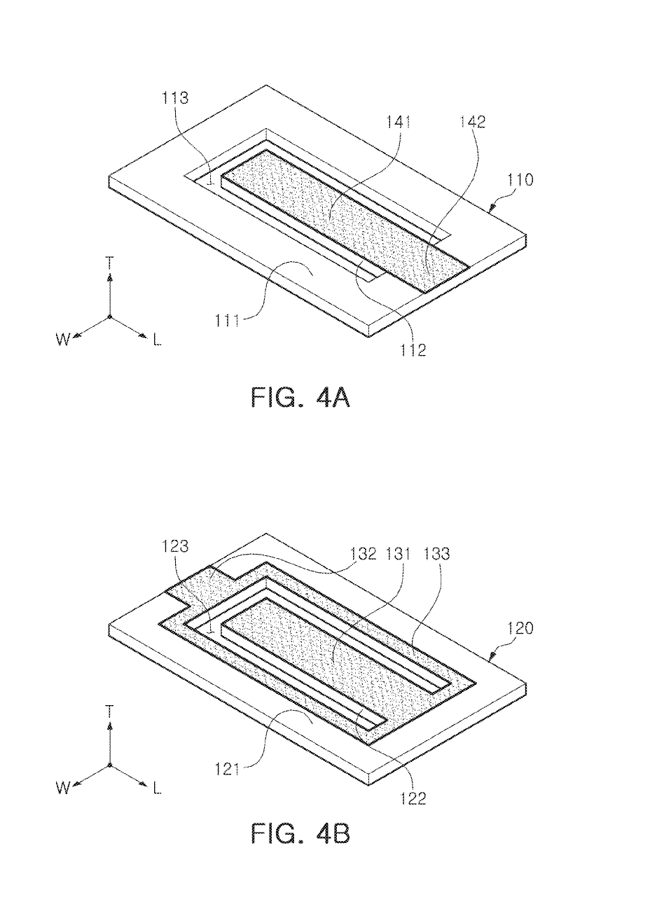

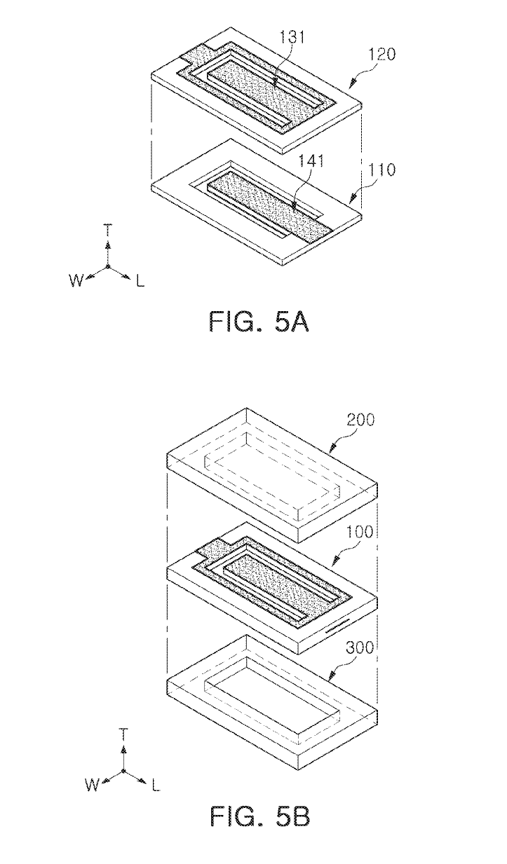

FIG. 4A is a perspective view illustrating a first piezoelectric sheet 110 of a piezoelectric element 100 in the piezoelectric shock sensor 10 of FIG. 1; and FIG. 4B is a perspective view illustrating a second piezoelectric sheet 120 of a piezoelectric element 100 in the piezoelectric shock sensor 10 of FIG. 1.

Referring to FIGS. 4A and 4B, the piezoelectric element 100 may have a structure in which a first piezoelectric sheet 110 disposed at a lower portion thereof and a second piezoelectric sheet 120 disposed at an upper portion thereof overlap each other in a vertical direction and are stacked. In the present exemplary embodiment, first and second internal electrodes 141 and 131 included in the piezoelectric element 100 may have a cantilever shape.

The first piezoelectric sheet 110 may have a first frame portion 111 and a first cantilever portion 112 formed integrally with each other.

The first frame portion 111 may have a shape of a frame having a first hole 113 formed at the center thereof, and the first cantilever portion 112 may be linearly extended from the first frame portion 111 toward the first hole 113.

In addition, the first internal electrode 141 may be formed on an upper surface of the first cantilever portion 112, and a first lead portion 142 may be formed on an upper surface of the first frame portion 111 so as to be exposed through a third surface of the piezoelectric element 100 in the length direction (see, e.g., FIGS. 2 and 3).

Here, the first internal electrode 141 may be exposed through edges of the first cantilever portion 112, thereby improving sensitivity when the piezoelectric shock sensor is operated.

Here, stress may be concentrated on a portion at which the first internal electrode 141 and the first lead portion 142 are connected to each other, and a vibration state of the first internal electrode 141 may be stably maintained.

In addition, the second piezoelectric sheet 120 may be formed of the same material as the first piezoelectric sheet 110, but is not necessarily limited thereto.

The second piezoelectric sheet 120 may have a second frame portion 121 and a second cantilever portion 122 formed integrally with each other.

The second frame portion 121 may have a shape of a frame having a second hole 123 formed at the center thereof, and the second cantilever portion 122 may be linearly extended from the second frame portion 121 toward the second hole 123. The second frame portion 121 may overlap the first frame portion 111 in the vertical direction when the second piezoelectric sheet 120 is mounted on the first piezoelectric sheet 110. Additionally, the second hole 123 may overlap the first hole 113 in the vertical direction when the second piezoelectric sheet 120 is mounted on the first piezoelectric sheet 110, and the second cantilever portion 122 may overlap the first cantilever portion 112 in the vertical direction when the second piezoelectric sheet 120 is mounted on the first piezoelectric sheet 110.

In addition, the second internal electrode 131 may be formed on an upper surface of the second cantilever portion 122. Further, a second lead portion 132 may be formed on an upper surface of the second frame portion 121, and may be formed so as to be exposed to a side surface of the second piezoelectric sheet 120 opposite a side surface of the first piezoelectric sheet 110 on which the first lead portion 142 is exposed. A connection portion 133 may be formed on the upper surface of the second frame portion 121 so as to connect the second internal electrode 131 and the second lead portion 132 to each other. The connection portion 133 may be formed along edges of the second hole 123 extending through the second frame portion 121.

Here, stress may be concentrated on a portion at which the second internal electrode 131 and the connection portion 133 are connected to each other, and a vibration state of the second internal electrode 131 may be stably maintained.

In addition, the connection portion 133 may be exposed through inner edges of the second hole 123, if necessary. For example, the connection portion 133 may have a quadrangular band shape in a case in which the second hole 123 has a quadrangular shape, but is not limited thereto.

In addition, first and second external electrodes 411 and 412 may be formed on external surface of the multilayer body of the piezoelectric shock sensor 10 formed by stacking the piezoelectric element 100 and the upper and lower covers 200 and 300.

The first and second external electrodes 411 and 412 may be formed on the third and fourth surfaces 3 and 4 of the multilayer body so as to respectively be electrically connected to exposed portions of the first and second lead portions 142 and 132. In the present exemplary embodiment, since the first and second lead portions 142 and 132 are exposed outwardly as described above, the external electrodes 411 and 412 may also be simply formed.

The first and second external electrodes 411 and 412 may optionally have band portions extending to portions of the first surface 1 of the multilayer body, portions of the second surface 2 of the multilayer body, and portions of the fifth and sixth surfaces 5 and 6 of the multilayer body in the width direction.

In addition, in the present exemplary embodiment, the piezoelectric element 100 may have a double-layer structure formed of the first and second piezoelectric sheets 110 and 120, and thus sensitivity of the piezoelectric shock sensor may be further improved. In one example, the second piezoelectric sheet 120 may be stacked on top of the first piezoelectric sheet 110 so as to contact the first piezoelectric sheet 110, such that the second frame portion 121 overlaps the first frame portion 111, the second hole 123 overlaps the first hole 113, and the second cantilever portion 122 overlaps the first cantilever portion 112, and such that the first and second lead portions 142 and 132 are exposed to opposing side surfaces of the resulting stacked structure.

Method of Manufacturing Piezoelectric Shock Sensor

Hereinafter, a method of manufacturing a piezoelectric shock sensor according to an exemplary embodiment will be described.

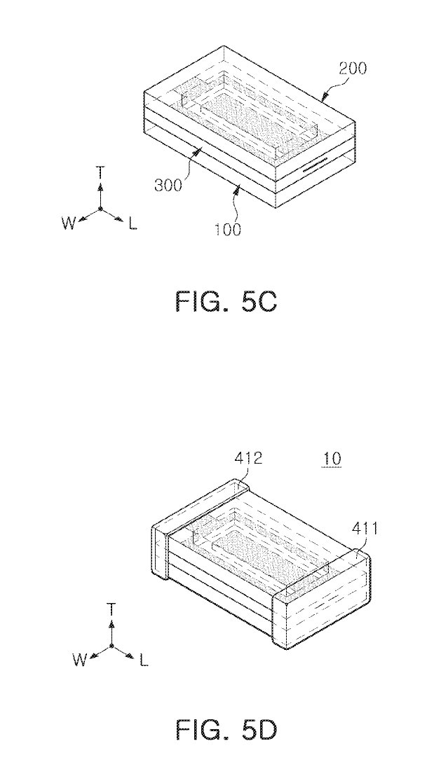

FIGS. 5A through 5D are perspective views illustrating sequential steps of a method of manufacturing a piezoelectric shock sensor according to an exemplary embodiment.

First, the first and second piezoelectric sheets 110 and 120 each having a predetermined thickness may be prepared.

The first piezoelectric sheet 110 may be formed of a piezoelectric material, and may have the first cantilever portion 112 and the first frame portion 111 formed integrally with each other and separated from each other by the first hole 113.

Here, the first cantilever portion 112 may be prepared by perforating the first hole 113 having a ‘ [symbol] ’ shape at the center of the first frame portion 111.

In addition, the first piezoelectric sheet 110 may be prepared by printing a conductive paste on the upper surface of the first cantilever portion 112 to form the first internal electrode 141 and printing a conductive paste on the upper surface of the first frame portion 111 to form the first lead portion 142. The first lead portion 142 may be formed so as to be exposed through the third surface 3 of the first piezoelectric sheet 110 in the length direction.

The second piezoelectric sheet 120 may be formed of a piezoelectric material, and may have the second cantilever portion 122 and the second frame portion 121 formed integrally with each other and separated from each other by the second hole 123.

Here, the second cantilever portion 122 may be prepared by perforating the second hole 123 having a ‘ [symbol] ’ shape at the center of the second frame portion 121.

In addition, the second piezoelectric sheet 120 may be prepared by printing a conductive paste on the upper surface of the second cantilever portion 122 to form the second internal electrode 131. In general, during operation of the piezoelectric shock sensor 10, different polarities are applied to the first internal electrode 141 and the second internal electrode 131. Further, the second piezoelectric sheet 120 may be prepared by printing a conductive paste on the upper surface of the second frame portion 121 to form the second lead portion 132. The second lead portion 132 may be formed so as to be exposed on a surface of the second piezoelectric sheet 120 that is opposite to a surface through which the first lead portion 142 is exposed. For example, the second lead portion 132 may be exposed through a fourth surface 4 of the second piezoelectric sheet 120 in the length direction. Finally, the second piezoelectric sheet 120 may be prepared by printing a conductive paste on the upper surface of the second frame portion 121 to form the connection portion 133 so that one end portion of the second internal electrode 131 and one end portion of the second lead portion 132 are electrically connected to each other.

In addition, the first and second piezoelectric sheets 110 and 120, respectively having the first and second internal electrodes 141 and 131 formed thereon, may be stacked in the vertical direction, as shown in FIG. 5A, to prepare and form the piezoelectric element 100.

Next, the piezoelectric element 100 may be disposed on the upper surface of the lower cover 300, as shown in FIG. 5B.

Next, the upper cover 200 may be disposed on the upper surface of the piezoelectric element 100 to complete the multilayer body, as shown in FIG. 5B.

Here, the first and second concave portions 310 and 210 may be formed in the upper surface of the lower cover 300 and the lower surface of the upper cover 200, respectively, prior to the assembly of the upper and lower covers 200 and 300 on the piezoelectric element 100.

Next, conductive metal pastes may be applied onto the third and fourth surfaces 3 and 4 of the multilayer body in which the lower cover 300, the piezoelectric element 100, and the upper cover 200 are stacked to form the first and second external electrodes 411 and 412, as shown in FIG. 5D. The first and second external electrodes 411 and 412 may thereby be electrically connected to the exposed portions of the first and second lead portions 142 and 132, respectively.

A piezoelectric shock sensor according to the related art may be manufactured by forming and polarizing two package structures on upper and lower surfaces or left and right surfaces of a piezoelectric body, cutting one end of an electrode to form a cantilever, and then bonding packages as covers to the piezoelectric body.

However, in a case of a method of manufacturing the piezoelectric shock sensor having the above-mentioned structure, a process of cutting the piezoelectric body is necessarily required in order to polarize internal electrodes and manufacture the internal electrodes in a cantilever shape. This may cause a manufacturing process to be complicated. Further, significant variation in the dimension of the cantilever may be generated by the cutting process, and thus a number of dimensional errors of the completed piezoelectric shock sensor may occur.

However, according to the present exemplary embodiment, the frame portion and the cantilever portion of the piezoelectric sheet may be formed integrally with each other, and the conductive paste may be printed on the piezoelectric sheet to form the internal electrode. Therefore, since a process of cutting the piezoelectric body is not required after the internal electrode is formed, a manufacturing process may be simplified, and a dimension dispersion generated in the cutting process according to the related art may not be present. Thus, a dimensional error of the completed piezoelectric shock sensor may advantageously be reduced.

As set forth above, according to an exemplary embodiment, the internal electrodes may be manufactured in the cantilever shape without performing a processing of cutting the piezoelectric element, and thus a manufacturing process may be simplified to improve productivity. Further, a dimensional error of the manufactured piezoelectric shock sensor may be reduced to improve a defect rate of a product.

While exemplary embodiments have been shown and described above, it will be apparent to those skilled in the art that modifications and variations could be made without departing from the scope of the present invention as defined by the appended claims.

What is claimed is:

1. A piezoelectric shock sensor comprising:
a lower cover;
a piezoelectric element including first and second piezoelectric sheets stacked in a vertical direction and disposed on an upper surface of the lower cover; and
an upper cover disposed on an upper surface of the piezoelectric element,
wherein the first piezoelectric sheet has a first cantilever portion and a first frame portion formed integrally with each other, and includes a first internal electrode formed on an upper surface of the first cantilever portion and a first lead portion formed on an upper surface of the first frame portion, and the first lead portion is electrically connected to the first internal electrode and extends so as to be exposed through one surface of the piezoelectric element in a length direction, and
the second piezoelectric sheet has a second cantilever portion and a second frame portion formed integrally with each other and respectively overlapping the first cantilever portion and the first frame portion in the vertical direction, and includes a second internal electrode formed on an upper surface of the second cantilever portion, a second lead portion formed on an upper surface of the second frame portion and extended so as to be exposed through another surface of the piezoelectric element opposing the one surface in the length direction, and a connection portion formed on the upper surface of the second frame portion so as to connect the second internal electrode and the second lead portion to each other.

2. The piezoelectric shock sensor of claim 1, further comprising first and second external electrodes formed on opposing end surfaces in the length direction of a multilayer body including the lower cover, the piezoelectric element, and the upper cover, wherein the first and second external electrodes are connected to exposed portions of the first and second lead portions, respectively.

3. The piezoelectric shock sensor of claim 1, wherein in the first piezoelectric sheet, the first frame portion has a first hole formed at a center thereof, and the first cantilever portion is linearly extended from the first frame portion toward the first hole, and
in the second piezoelectric sheet, the second frame portion has a second hole formed at a center thereof, and the second cantilever portion is linearly extended from the second frame portion toward the second hole.

4. The piezoelectric shock sensor of claim 3, wherein the connection portion is exposed to inner edges of the second hole.

5. The piezoelectric shock sensor of claim 1, wherein first and second concave portions are respectively formed in the upper surface of the lower cover and a lower surface of the upper cover.

6. A method of manufacturing a piezoelectric shock sensor, comprising:
preparing a piezoelectric element by stacking first and second piezoelectric sheets respectively having a first internal electrode and a second internal electrode in a vertical direction;
disposing the piezoelectric element on an upper surface of a lower cover; and
disposing an upper cover on an upper surface of the piezoelectric element,
wherein the preparing the piezoelectric element comprises:
forming a first cantilever portion and a first frame portion integrally with each other in the first piezoelectric sheet,
forming the first internal electrode using a conductive paste on an upper surface of the first cantilever portion,
forming a first lead portion using the conductive paste on an upper surface of the first frame portion so as to be exposed to one end surface of the first piezoelectric sheet in a length direction,
forming a second cantilever portion and a second frame portion integrally with each other in the second piezoelectric sheet,
forming the second internal electrode using the conductive paste on an upper surface of the second cantilever portion,
forming a second lead portion using the conductive paste on an upper surface of the second frame portion so as to be exposed to another end surface of the first piezoelectric sheet opposing the one end surface in the length direction, and
forming a connection portion using the conductive paste so that one end portion of the second internal electrode and one end portion of the second lead portion are electrically connected to each other through the connection portion.

7. The method of claim 6, further comprising:
forming first and second external electrodes on opposing end surfaces in the length direction of a multilayer body including the lower cover, the piezoelectric element, and the upper cover,
wherein the first and second external electrodes are formed so as to be connected to exposed portions of the first and second lead portions, respectively.

8. The method of claim 6, wherein the forming the first cantilever portion comprises perforating a first hole having a ‘ [symbol] ’ shape at a center of the first frame portion, and
the forming the second cantilever portion comprises perforating a second hole having a ‘ [symbol] ’ shape at a center of the second frame portion.

9. The method of claim 8, wherein the forming the connection portion comprises forming the connection portion to be exposed to inner edges of the second hole.

10. The method of claim 6, further comprising:
forming first and second concave portions in the upper surface of the lower cover and a lower surface of the upper cover, respectively, prior to the steps for disposing the piezoelectric element on the lower cover and for disposing the upper cover on the piezoelectric element.

11. A method of manufacturing a piezoelectric element, comprising:
forming a first piezoelectric sheet having a first cantilever portion disposed in a central portion thereof;
forming a first internal electrode on an upper surface of the first cantilever portion of the first piezoelectric sheet;
forming a second piezoelectric sheet having a second cantilever portion disposed in a central portion thereof and having a same shape as the first cantilever portion;
forming a second internal electrode on an upper surface of the second cantilever portion of the second piezoelectric sheet; and
stacking the second piezoelectric sheet on an upper surface of the first piezoelectric sheet, wherein the stacking comprises stacking the second cantilever portion on the upper surface of the first cantilever portion having the first internal electrode formed thereon.

12. The method of claim 11, wherein:
the forming the first piezoelectric sheet comprises forming the first piezoelectric sheet to have a first frame portion with a first hole in a center thereof and the first cantilever portion integrally formed with the first frame portion and extending toward the first hole; and
the forming the second piezoelectric sheet comprises forming the second piezoelectric sheet to have a second frame portion with a second hole in a center thereof and the second cantilever portion integrally formed with the second frame portion and extending toward the second hole.

13. The method of claim 12, wherein the forming the second piezoelectric sheet comprises forming the second frame portion having a same shape as the first frame portion, forming the second hole having a same shape as the first hole, and forming the second cantilever portion having a same shape as the first cantilever portion.

14. The method of claim 12, wherein:
the forming the first internal electrode further comprises forming a first lead portion on the upper surface the first piezoelectric sheet, the first lead portion contacting the first internal electrode and extending to a lateral surface of the first piezoelectric sheet, and
the forming the second internal electrode further comprises forming a second lead portion and a connection portion on the upper surface the second piezoelectric sheet, the second lead portion and the connection portion extending from the second internal electrode and to a lateral surface of the second piezoelectric sheet.

15. A method of manufacturing a piezoelectric shock sensor, comprising:
manufacturing a piezoelectric element in accordance with the method of claim 11;
disposing the piezoelectric element on an upper surface of a lower cover having a concave portion formed in the upper surface; and
disposing an upper cover on an upper surface of the piezoelectric element, the upper cover having a concave portion formed in a lower surface thereof that contacts the upper surface of the piezoelectric element.

16. The method of claim 15, further comprising:
forming first and second external electrodes on opposing end surfaces in the length direction of a multilayer body including the lower cover, the piezoelectric element, and the upper cover,
wherein the first and second external electrodes are formed so as to be connected to exposed portions of the first and second lead portions, respectively.
